(19) United States
(12) Patent Application Publication
(10) Pub. No.: US 2024/0299933 A1
(43) Pub. Date: Sep. 12, 2024

(54) MICROFLUIDIC CHIP AND USAGE METHOD THEREOF, AND MICROFLUIDIC SYSTEM

(71) Applicants: Beijing BOE Technology Development Co., Ltd., Beijing (CN); BOE Technology Group Co., Ltd., Beijing (CN)

(72) Inventors: Kang PENG, Beijing (CN); Ding DING, Beijing (CN); Zhukai LIU, Beijing (CN)

(21) Appl. No.: 18/024,892

(22) PCT Filed: Mar. 15, 2022
(86) PCT No.: PCT/CN2022/080896

§ 371 Date: Mar. 6, 2023

(51) Int. Cl. B01L 3/00; H01L 27/12

(52) U.S. Cl. CPC B01L 3/502715; B01L 2200/0647; B01L 2200/12; B01L 2300/04; B01L 2300/0645; B01L 2300/161; B01L 2400/06; H01L 27/1214

(57) ABSTRACT

Provided are a microfluidic chip and a usage method thereof, and a microfluidic system. The microfluidic chip includes a substrate layer, the substrate layer includes a substrate and a drive electrode layer; and a cover plate layer arranged opposite the substrate layer, a space between the cover plate layer and the substrate layer form a solution accommodating space; the cover plate layer includes a solution inlet hole, a solution outlet hole, and limiting recesses arranged on a side of the cover plate layer facing the substrate layer, the solution inlet hole, the solution outlet hole and each limiting recess are in communication with the solution accommodating space, and an end surface of the solution inlet hole adjacent to the substrate layer, an end surface of the solution outlet hole adjacent to the substrate layer, and opening surfaces of the plurality of limiting recesses are arranged substantially flush with one another.

### CROSS REFERENCE TO RELATED APPLICATIONS

The present disclosure is a National Stage of International Application No. PCT/CN2022/080896, filed Mar. 15, 2022.

### FIELD

The present disclosure relates to the field of a microfluidic technology, and particularly relates to a microfluidic chip and a usage method thereof, and a microfluidic system.

### BACKGROUND

Based on micron-scaled fluid manipulation, a microfluidic chip technology realizes a complex biochemical reaction process on a small-scale chip. Accordingly, large-scale analytical instruments keep being upgraded towards miniaturization, integration, automation, high-throughput and so on, which promotes the development of real-time detection and on-site analysis with rapid quantification as the core.

### SUMMARY

Embodiments of the present disclosure provide a microfluidic chip and a usage method thereof, and a microfluidic system. The solutions are as follows.

In one aspect, an embodiment of the present disclosure provides a microfluidic chip. The microfluidic chip includes:
a substrate layer, where the substrate layer includes a substrate and a drive electrode layer disposed on the substrate; and
a cover plate layer, arranged opposite the substrate layer, where a space between the cover plate layer and the substrate layer form a solution accommodating space; and the cover plate layer includes a solution inlet hole penetrating a thickness direction of the cover plate layer; and a solution outlet hole penetrating the thickness direction of the cover plate layer, and a plurality of limiting recesses arranged in an array on a side of the cover plate layer facing the substrate layer, the solution inlet hole, the solution outlet hole and the plurality of limiting recesses are in communication with the solution accommodating space, and an end surface of the solution inlet hole adjacent to the substrate layer, an end surface of the solution outlet hole adjacent to the substrate layer, and opening surfaces of the plurality of limiting recesses are arranged substantially flush with one another.

In some embodiments, in the microfluidic chip provided in the embodiments of the present disclosure, the cover plate layer further includes a reaction recess, the reaction recess arranged on the side of the cover plate layer facing the substrate layer, and the reaction recess and the substrate layer form the solution accommodating space; and
a bottom surface of the reaction recess is arranged substantially flush with the end surface of the solution inlet hole adjacent to the substrate layer, the end surface of the solution outlet hole adjacent to the substrate layer, and the opening surfaces of the plurality of limiting recesses.

In some embodiments, in the microfluidic chip provided in the embodiments of the present disclosure, the reaction recess and the plurality of limiting recesses are integrally injection-molded.

In some embodiments, in the microfluidic chip provided in the embodiments of the present disclosure, the cover plate layer further includes a gas valve cavity independent from the plurality of limiting recesses, and a gas inlet channel and a gas outlet channel, the gas inlet channel and the gas outlet channel are in communication with the gas valve cavity; and
the gas valve cavity is arranged on a side of the plurality of limiting recesses facing away from the substrate layer, and an orthographic projection of the gas valve cavity on the substrate covers orthographic projections of the plurality of limiting recesses on the substrate.

In some embodiments, in the microfluidic chip provided in the embodiments of the present disclosure, the gas valve cavity and the plurality of limiting recesses are integrally injection-molded, or a portion where the gas valve cavity is located and a portion where the plurality of limiting recesses are located are fixedly connected with each other through glue.

In some embodiments, in the microfluidic chip provided in the embodiments of the present disclosure, a volume of each of the limiting recesses is substantially a same.

In some embodiments, in the microfluidic chip provided in the embodiments of the present disclosure, the drive electrode layer includes a first electrode, a second electrode and a plurality of third electrodes arranged in an array, an orthographic projection of the first electrode on the substrate covers an orthographic projection of the solution inlet hole on the substrate, an orthographic projection of the second electrode on the substrate covers an orthographic projection of the solution outlet hole on the substrate, and orthographic projections of the plurality of third electrodes on the substrate and the orthographic projections of the plurality of limiting recesses on the substrate overlap each other.

In some embodiments, in the microfluidic chip provided in the embodiments of the present disclosure, an orthographic projection of one of the limiting recesses on the substrate covers an orthographic projection of at least one of the third electrodes on the substrate.

In some embodiments, in the microfluidic chip provided in the embodiments of the present disclosure, the substrate layer further includes a plurality of transistors arranged between the substrate and the drive electrode layer, and the plurality of transistors are electrically connected with the third electrodes.

In some embodiments, in the microfluidic chip provided in the embodiments of the present disclosure, the drive electrode layer further includes a plurality of first connection electrodes, and the plurality of first connection electrodes are arranged between the first electrode and the plurality of third electrodes, and the plurality of first connection electrodes are arranged between the second electrode and the plurality of third electrodes.

In some embodiments, in the microfluidic chip provided in the embodiments of the present disclosure, a main channel region, a connection channel region, and at least one branch channel region are provided between the first electrode and the plurality of third electrodes, and between the second electrode and the plurality of third electrodes separately, and the at least one branch channel region is connected with the main channel region by means of the connection channel region; the main channel region is arranged adjacent to the first electrode and the second electrode, and the branch channel region is arranged adjacent to the plurality of third electrodes; and each of the main channel region, the connection channel region, and the branch channel regions is provided with a plurality of the first connection electrodes separately.

In some embodiments, in the microfluidic chip provided in the embodiments of the present disclosure, the cover plate layer further includes a first connection channel and at least one solution storage recess, an orthographic projection of the first connection channel on the substrate and an orthographic projection of the at least one solution storage recess on the substrate do not overlap an orthographic projection of the solution accommodating space on the substrate; and
the solution storage recess is concaved inwards from a surface of a side of the cover plate layer facing away from the substrate layer towards the cover plate layer, the first connection channel is arranged inside the cover plate layer, and the solution storage recess is in communication with the solution inlet hole through the first connection channel.

In some embodiments, in the microfluidic chip provided in the embodiments of the present disclosure, the cover plate layer further comprises a plurality of solution storage recesses; and a second connection channel enabling communication between the solution storage recesses, the second connection channel is arranged inside the cover plate layer, and an orthographic projection of the second connection channel on the substrate does not overlap the orthographic projection of the solution accommodating space on the substrate.

In some embodiments, in the microfluidic chip provided in the embodiments of the present disclosure, the drive electrode layer further includes: a plurality of fourth electrodes corresponding one-to-one to the solution storage recesses, a plurality of second connection electrodes corresponding to the first connection channel and arranged in an array, and a plurality of third connection electrodes corresponding to the second connection channel and arranged in an array.

In some embodiments, in the microfluidic chip provided in the embodiments of the present disclosure, the solution storage recesses include at least one of a sample storage recess, a magnetic bead and lysis solution storage recess, a washing solution storage recess, an eluate storage recess, a lysis waste solution storage recess, a washing waste solution storage recess, a magnetic bead waste solution storage recess, or a product storage recess.

In some embodiments, in the microfluidic chip provided in the embodiments of the present disclosure, the substrate layer further includes a hydrophobic layer arranged on an entire surface of a side of the drive electrode layer away from the substrate.

In another aspect, an embodiment of the present disclosure provides a microfluidic system including the microfluidic chip provided in the embodiments of the present disclosure.

In another aspect, an embodiment of the present disclosure provides a usage method for the microfluidic chip. The usage method includes:
injecting a reaction solution into the solution accommodating space through the solution inlet hole;
loading the drive electrode layer with an electric signal, to disperse the reaction solution into a plurality of droplets under a driving action of the drive electrode layer;
applying pressure to the cover plate layer, to make each of the droplets enter a space defined by the limiting recesses and the substrate layer and isolated from each other; and
after a reaction is completed, discharging a solution from the solution accommodating space through the solution outlet hole.

In some embodiments, in the usage method provided in the embodiments of the present disclosure, the applying pressure to the cover plate layer, to make each of the droplets enter a space defined by the limiting recesses and the substrate layer and isolated from each other specifically includes:
inflating and pressurizing the gas valve cavity, to make the gas valve cavity drive the plurality of limiting recesses to move towards the substrate layer until the opening surfaces of the limiting recesses make contact with the substrate layer, so as to make each of the droplets enter the space defined by the limiting recesses and the substrate layer and isolated from each other.

In some embodiments, in the usage method provided in the embodiments of the present disclosure, the applying pressure to the cover plate layer, to make each of the droplets enter a space defined by the limiting recesses and the substrate layer and isolated from each other specifically includes:
applying pressure to the cover plate layer by using a weight on the side of the cover plate layer facing away from the substrate layer until the opening surfaces of the limiting recesses make contact with the substrate layer, so as to make each of the droplets enter the space defined by the limiting recesses and the substrate layer and isolated from each other.

### BRIEF DESCRIPTION OF THE DRAWINGS

FIG. 1 is a schematic structural diagram of a substrate layer provided in an embodiment of the present disclosure.

FIG. 2 is a schematic structural diagram of a cover plate layer provided in an embodiment of the present disclosure.

FIG. 3 is a schematic structural diagram after the substrate layer shown in FIG. 1 is opposed to the cover plate layer shown in FIG. 2.

FIG. 4 is a sectional view along line I-I′ of FIG. 3.

FIG. 5 is a schematic diagram of a depressed region Z₁ of FIG. 4.

FIG. 6 is a schematic diagram of active driving for a plurality of third electrodes provided in an embodiment of the present disclosure.

FIG. 7 is a sectional view along line II-II′ of FIG. 6.

FIG. 8 is a schematic enlarged structural diagram of a region Z₂ of FIG. 7.

FIG. 9 is a structural schematic diagram of a microfluidic chip provided in an embodiment of the present disclosure.

FIG. 10 is a sectional view along line III-III′ of FIG. 9.

FIG. 11 is a sectional view along line IV-IV′ of FIG. 9.

FIG. 12 is a flowchart of a usage method for a microfluidic chip provided in an embodiment of the present disclosure.

FIG. 13 is a schematic diagram of physical separation between droplets by a microfluidic chip provided in an embodiment of the present disclosure.

FIG. 14 is a schematic diagram of physical separation between droplets by a microfluidic chip provided in an embodiment of the present disclosure.

### DETAILED DESCRIPTION OF THE EMBODIMENTS

In order to make the objectives, technical solutions, and advantages in the embodiments of the present disclosure clearer, the technical solutions in the embodiments of the present disclosure will be clearly and completely described below with reference to the accompanying drawings in the embodiments of the present disclosure. It should be noted that sizes and shapes of all figures in the accompanying drawings do not reflect true scales, and are merely intended to illustrate contents of the present disclosure. Moreover, the same or similar reference numerals denote the same or similar elements or elements having the same or similar function throughout.

Unless otherwise defined, technical or scientific terms used herein should have ordinary meanings as understood by those of ordinary skill in the art to which the present disclosure belongs. “First”, “second” and similar words used in the description and claims of the present disclosure do not mean any order, quantity or importance, but are only used for distinguishing different components. “Comprise”, “include” and similar words are intended to mean that an element or item in front of the word encompasses elements or items that are listed behind the word and equivalents thereof, but do not exclude other elements or items. “Inner”, “outer”, “upper”, “lower”, etc. are merely used to indicate a relative positional relation, and when an absolute position of the described object is changed, the relative positional relation can also be changed accordingly.

There have been various biochemical reactions that can be integrated on a microfluidic chip. A polymerase chain reaction (PCR) is one of the biochemical reactions. PCR is a classical molecular biological experimental technology that can synthesize a large amount of target deoxyribonucleic acid (DNA) fragments by enzymatic reaction in vitro. With the features of strong specificity, high sensitivity, easy operation, etc., PCR is widely used in gene cloning, sequence analysis, disease diagnosis, pathogen detection, etc.

Digital PCR is a third-generation quantitative nucleic acid analysis technology developed rapidly in recent years. A principle of the digital PCR is to evenly distribute a sample to tens of thousands of different reaction units, each unit containing at least one copy of a target DNA template, then perform PCR amplification in each reaction unit separately, and perform statistical analysis on fluorescence signals of each reaction unit after amplification. Being independent of a standard curve, the digital PCR is less influenced by amplification efficiency, has desirable accuracy and reproducibility, and can achieve absolute quantitative analysis, with great technical advantages in nucleic acid detection, identification and other research fields. Currently, implementation forms of the digital PCR mainly include array-type chips and droplet-type chips. With respect to the array-type chips, two solution phases need to be added successively, an added aqueous reaction solution is easily washed out by the later added oil phase, and bubbles are easily introduced when adding a sample, resulting in aerosol contamination or interference between solutions of reaction units in the PCR process. For the droplet-type chips, the lack of physical separation between droplets tends to cause interference and poor dispersion stability in the oil phase. These disadvantages restrict the practical application of the digital PCR technology.

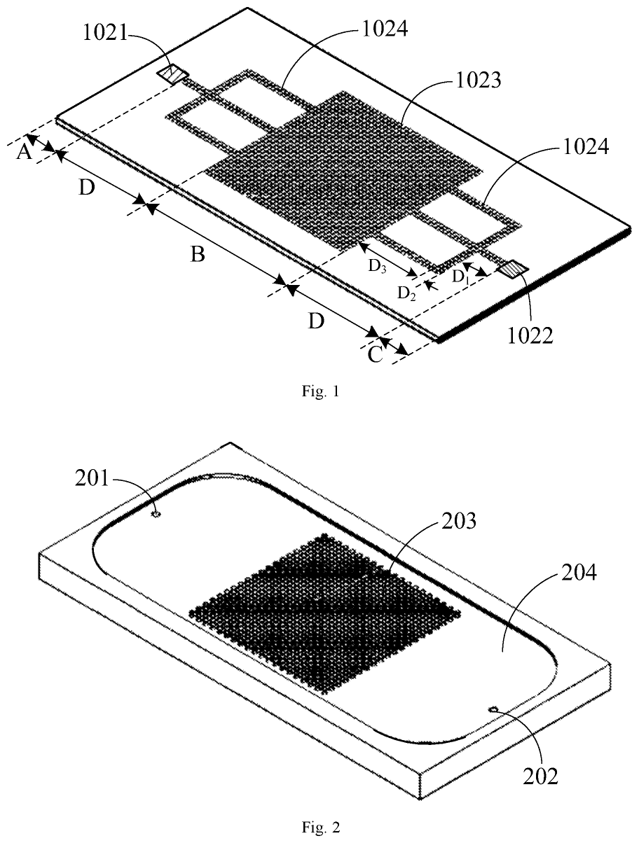

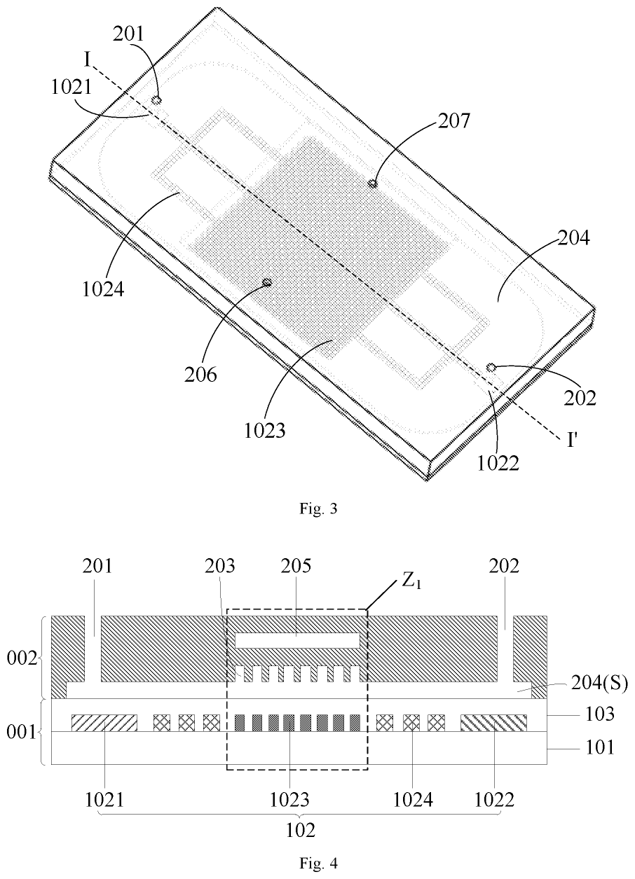

In order to solve the above technical problems existing in the related art, embodiments of the present disclosure provide a microfluidic chip, as shown in FIGS. 1 to 5, including:
a substrate layer 001, where the substrate layer 001 includes a substrate 101, and a drive electrode layer 102 disposed on the substrate 101, and In some embodiments, the substrate 101 may be made of glass or other hard materials; and
a cover plate 002 layer arranged opposite the substrate layer 001, where a space between the cover plate layer 002 and the substrate layer 001 form a solution accommodating space S; and the cover plate layer 002 includes a solution inlet hole 201 and a solution outlet hole 202 that penetrate a thickness direction of the cover plate layer, and a plurality of limiting recesses 203 arranged in an array on a side of the cover plate layer 002 facing the substrate layer 001, the solution inlet hole 201, the solution outlet hole 202 and the plurality of limiting recesses 203 are all in communication with the solution accommodating space S, and an end surface of the solution inlet hole 201 adjacent to the substrate layer 001, an end surface of the solution outlet hole 202 adjacent to the substrate layer 001, and opening surfaces of the plurality of limiting recesses 203 are arranged substantially flush with one another (that is, exactly flush or within a tolerance range due to fabrication, measurement, etc.). Under the action of pressure, in the solution accommodating space S, the opening surface of each of the limiting recesses 203 make contact with the substrate layer 001, such that the space (which can be used for accommodating droplets) defined by each of the limiting recesses 203 and the substrate layer 001 is separated from each other. In some embodiments, the cover plate layer 002 may be made of Polydimethylsiloxane (PDMS) or other resilient plastic, such that minimal pressure may be applied to deform the cover plate layer 002 into contact with the substrate layer 001. In some embodiments, a region where the solution inlet hole 201 is located may be marked as a solution inlet region A, a region where the plurality of limiting recesses 203 are located may be marked as a reaction region B, a region where the solution outlet hole 202 is located may be marked as a solution outlet region C, and the solution accommodating space S may cover the solution inlet region A, the reaction region B and the solution outlet region C.

In the above microfluidic chip provided in the embodiments of the present disclosure, using the drive electrode layer 102 to drive may achieve uniform and rapid dispersion of droplets, so as to avoid the problems such as bubbles, dead volume or insufficient sample injection of reaction solution which are easily occurred during sample injection of a common micro-well array chip, and improve the accuracy of a detection result. Moreover, the physical separation between droplets is achieved by cooperation between the limiting recesses 203 and the substrate layer 001, so as to avoid the phenomenon that the droplet-type chip cannot achieve physical separation in the related art, guarantee stability of a reaction system, prevent the influence of interference between droplets, and improve the stability and reliability of the detection result.

In some embodiments, in the microfluidic chip provided in the embodiments of the present disclosure, as shown in FIGS. 2 and 4, the side of the cover plate layer 002 facing the substrate layer 001 is provided with a reaction recess 204, and the reaction recess 204 and the substrate layer 001 define the solution accommodating space S. In this way, no recess needs to be provided in the substrate layer 001, which guarantees the surface flatness of the substrate layer 001 and facilitates movement of the droplets. In some embodiments, a bottom surface of the reaction recess 204 may be arranged substantially flush (that is, exactly flush or within a tolerance range due to fabrication, measurement, etc.) with the end surface of the solution inlet hole 201 adjacent to the substrate layer 001, the end surface of the solution outlet hole 202 adjacent to the substrate layer 001, and the opening surfaces of the plurality of limiting recesses 203.

In some embodiments, in the microfluidic chip provided in the embodiments of the present disclosure, the reaction recess 204 and the plurality of limiting recesses 203 may be integrally injection-molded, so as to simplify processes and reduce costs.

In some embodiments, in the microfluidic chip provided in the embodiments of the present disclosure, as shown in FIGS. 2 and 4, the cover plate layer 002 may further include a gas valve cavity 205 independent from the plurality of limiting recesses 203, and a gas inlet channel 206 and a gas outlet channel 207 that are in communication with the gas valve cavity 205; and the gas valve cavity 205 is located on a side of the plurality of limiting recesses 203 facing away from the substrate layer 001, and an orthographic projection of the gas valve cavity 205 on the substrate 101 covers (that is, is greater than or equal to) orthographic projections of the plurality of limiting recesses 203 on the substrate 101. In practical application, the gas outlet channel 207 may be closed, and the gas valve cavity 205 may be inflated and pressurized through the gas inlet channel 206, such that the limiting recesses 203 below the gas valve cavity 205 move downwards to make contact with the substrate layer 001, thereby using the limiting recesses 203 to store all droplets into the limiting recesses 203 to achieve physical separation, and after deformation of the cover plate layer 002 is stabilized, the gas inlet channel 206 is closed. Thus, it is achieved that the cover plate layer 002 is pressurized by means of the gas valve cavity 205, such that the limiting recesses 203 below the gas valve cavity 205 move downwards to make contact with the substrate layer 001. Certainly, in some embodiments, a weight may be used to press down on the cover plate layer 002, such that the limiting recesses 203 below the gas valve cavity 205 move downwards to make contact with the substrate layer 001.

In some embodiments, in the microfluidic chip provided in the embodiments of the present disclosure, the gas valve cavity 205 and the plurality of limiting recesses 203 are integrally injection-molded, or a portion where the gas valve cavity 205 is located and a portion where the plurality of limiting recesses 203 are located are fixedly connected with each other through glue. In this case, the gas valve cavity 205 may be formed by one injection molding process, and the limiting recesses 203 and the reaction recess 204 may be formed by another injection molding process. A mature injection molding process may be used to effectively reduce costs and improve production efficiency. In some embodiments, in order to improve the fixed connection effect between the portion where the gas valve cavity 205 is located and the portion where all the limiting recesses 203 are located, the glue may be laminated between the portion where the gas valve cavity 205 is located and all the limiting recesses 203 in a whole layer, and is hollowed out at the solution inlet hole 201 and the solution outlet hole 202.

In some embodiments, as shown in FIG. 4, the present disclosure provides the cover plate layer 002 having a thickness of 7 mm, a perpendicular distance between the gas valve cavity 205 and a surface of the side of the cover plate layer 002 facing away from the substrate layer 001 is 2 mm, a size of the gas valve cavity 205 may be 47 mm×47 mm×2 mm, two sides of the gas valve cavity 205 are provided with a gas inlet channel 206 and a gas outlet channel 207 in communication therewith, and the gas inlet channel 206 and the gas outlet channel 207 may both have a diameter of 1.5 mm and a depth of 2 mm. The plurality of limiting recesses 203 are arranged in an array at a perpendicular distance of 1 mm below the gas valve cavity 205, the single limiting recess 203 has a diameter of 1.4 mm and a depth of 1 mm, and a protrusion width between the limiting recesses 203 is 0.14 mm. A surface of the cover plate layer 001 adjacent to the substrate layer 001 has an elliptical reaction recess 204 with a depth of 1 mm, and two ends of the reaction recess 204 are provided with a solution inlet hole 201 and a solution outlet hole 202 with a diameter of 2 mm and a depth of 6 mm.

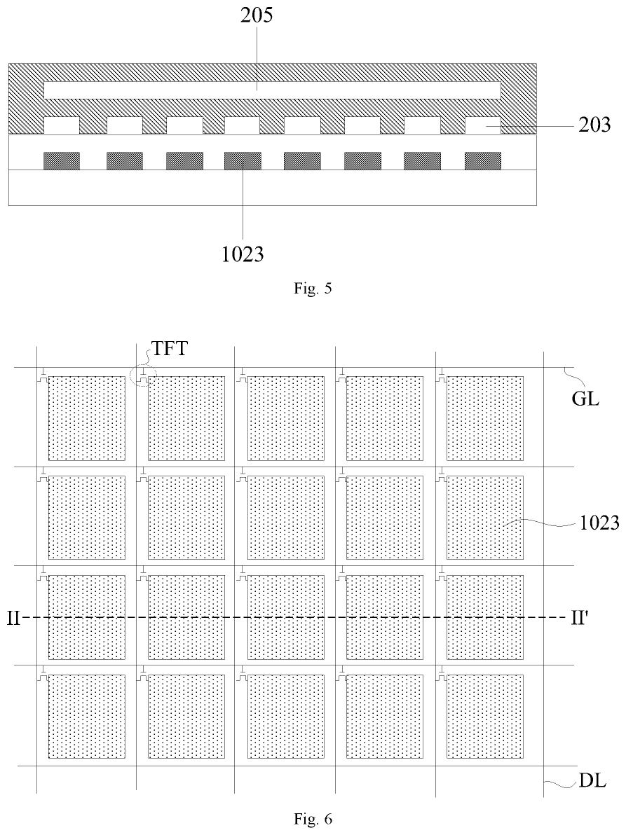

In some embodiments, in the microfluidic chip provided in the embodiments of the present disclosure, as shown in FIG. 5, a volume of each of the limiting recesses 203 is substantially the same, which advantageously guarantees that the uniformity of the volume of the droplet in each of the limiting recesses 203 is better. In the present disclosure, “substantially the same” may be identical or may have some deviation (for example, +5% deviation) due to the influence of other factors such as limitation of process conditions or measurement, and therefore the relationship of “substantially the same” between relevant features falls within the scope of the protection of the present disclosure as long as the tolerance is satisfied.

In some embodiments, in the microfluidic chip provided in the embodiments of the present disclosure, as shown in FIGS. 1 and 4, the drive electrode layer 102 may include a first electrode 1021, a second electrode 1022 and a plurality of third electrodes 1023 arranged in an array, an orthographic projection of the first electrode 1021 on the substrate 100 may be located in the solution inlet region A and cover (that is, greater than or equal to) an orthographic projection of the solution inlet hole 201 on the substrate 101, an orthographic projection of the second electrode 1022 on the substrate 101 may be located in the solution outlet region C and cover (that is, greater than or equal to) an orthographic projection of the solution outlet hole 202 on the substrate 101, and orthographic projections of the plurality of third electrodes 1023 on the substrate 101 may be located in the reaction region B and overlap the orthographic projections of the plurality of limiting recesses 203 on the substrate 101. In this case, a reaction solution injected to the first electrode 1021 through the solution inlet hole 201 may move to the third electrodes 1023 under a driving action of the first electrode 1021 and the third electrodes 1023, and be dispersed into droplets at each of the third electrodes 1023 under a driving action of the plurality of third electrodes 1023, and finally all the droplets move to the second electrode 1022 under a driving action of the third electrodes 1023 and the second electrode 1022, and are discharged from the solution outlet hole 202 above the second electrode 1022.

In some embodiments, in the microfluidic chip provided in the embodiments of the present disclosure, in order to facilitate storage of the droplets at the third electrodes 1023 by the limiting recesses 203, the orthographic projection of one limiting recess 203 on the substrate 101 may cover (that is, greater than or equal to) the orthographic projection of at least one third electrode 1023 on the substrate 101. For example, in FIG. 5, the orthographic projection of one limiting recess 203 on the substrate 101 and the orthographic projection of one third electrode 1023 on the substrate 101 substantially coincide (that is, exactly coincide or within an error range due to measurement, fabrication, etc.). In this case, a width of a gap between two adjacent third electrodes 1023 may be substantially equal (that is, exactly equal or within an error range due to measurement, fabrication, etc.) to the protrusion width between two adjacent limiting recesses 203. For another example, the orthographic projection of one limiting recess 203 on the substrate 101 correspondingly covers (that is, is greater than or equal to) the orthographic projection of two or more third electrodes 1023 on the substrate 101, and the two or more third electrodes 1023 corresponding to the one limiting recess 203 are taken as a group. In this case, in order to facilitate storage of the droplets at the third electrode 1023 by the limiting recess 203, a width of a gap between adjacent third electrodes 1023 in the same group may be less than or equal to half of the protrusion width between two adjacent limiting recesses 203, a width of a gap between two adjacent groups may be substantially equal (that is, exactly equal or within error range due to measurement, fabrication, etc.) to the protrusion width between two adjacent limiting recesses 203.

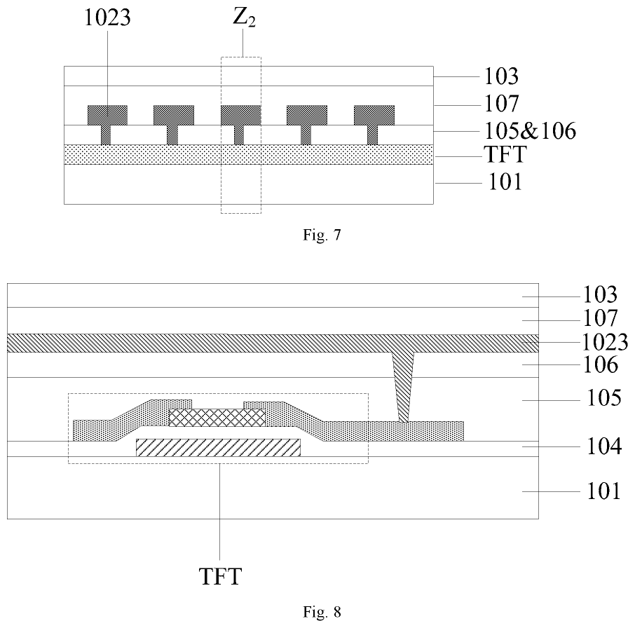

In some embodiments, in the microfluidic chip provided in the embodiments of the present disclosure, as shown in FIGS. 6 to 8, the microfluidic chip may further includes a plurality of transistor TFT located between the drive electrode layer 102 and the substrate 101, the transistors TFT are electrically connected with the third electrodes 1023. In some embodiments, in the present disclosure, each third electrode 1023 may be correspondingly electrically connected with one transistor TFT, the third electrodes 1023 in the same row are correspondingly electrically connected with one scanning line GL by means of the corresponding transistors TFT, and the third electrodes 1023 in the same column are correspondingly electrically connected with one data line DL by means of the corresponding transistors TFT, so as to achieve active driving for each third electrode 1023. In some embodiments, the transistors TFT may be top gate type transistors, bottom gate type transistors (as shown in FIG. 8) or double gate type transistors, and an active layer material of each transistor TFT may be amorphous silicon, low temperature polysilicon, an oxide (for example, indium gallium zinc oxide), etc. The scanning lines GL may be arranged on the same layer as gate electrodes of the transistors TFT, and the data line DL may be arranged on the same layer as source electrodes and drain electrodes of the transistors TFT.

In some embodiments, in the microfluidic chip provided in the embodiments of the present disclosure, as shown in FIGS. 1 and 4, the drive electrode layer 102 may further include a plurality of first connection electrodes 1024, the plurality of first connection electrodes 1024 are located between the first electrode 1021 and all the third electrodes 1023, and between the second electrode 1022 and all the third electrodes 1023. In some embodiments, a region where the plurality of first connection electrodes 1024 are located may be marked as a connection region D, and the first connection electrodes 1024 may form at least one row within the connection region D. Driven by the first connection electrodes 1024, the reaction solution rapidly disperses into a plurality of droplets and moves to the plurality of third electrodes 1023, such that the reaction solution disperses into a plurality of droplets before moving to the plurality of third electrodes 1023, which subsequently accelerates a process of distributing the droplets to the third electrodes 1023 advantageously. In some embodiments, the first connection electrodes 1024 in the present disclosure are also loaded with electric signals in an active driving mode as shown in FIG. 6.

In some embodiments, in the microfluidic chip provided in the embodiments of the present disclosure, as shown in FIG. 1, in order to accelerate the dispersion and transfer speed of the droplets, the region (that is, the connection region D) between the first electrode 1021 and all the third electrodes 1023, and the region (that is, the connection region D) between the second electrode 1022 and all the third electrodes 1023 may be divided into a main channel region D₁, a connection channel region D₂, at least one branch channel region D₃ separately, all the branch channel regions D₃ are directly connected with the main channel region D₁ by means of the connection channel region D₂, the main channel region D₁ is arranged adjacent to the first electrode 1021 and the second electrode 1022, and the branch channel regions D₃ are arranged adjacent to the plurality of third electrodes 1023; and the main channel region D₁, the connection channel region D₂ and the branch channel regions D₃ are provided with a plurality of first connection electrodes 1024 separately. In some embodiments, the first connection electrodes 1024 forms at least one row in each of the main channel region D₁, the connection channel region D₂, and the branch channel regions D₃ separately.

In some embodiments, in the present disclosure, the substrate layer 001 may have a thickness of 2 mm, the single third electrode 1023 may have a size of 1 mm×1 mm×0.1 mm, and the number of the third electrodes 1023 may be 40×40. The first electrode 1021 and the second electrode 1022 may be located on two sides of the third electrodes 1023, and the first electrode 1021 and the second electrode 1022 may both have a size 5 mm×5 mm×0.1 mm, such that the first electrode 1021 and the second electrode 1022 may function as a solution reservoir. The size of the first connection electrodes 1024 may also be 1 mm×1 mm×0.1 mm.

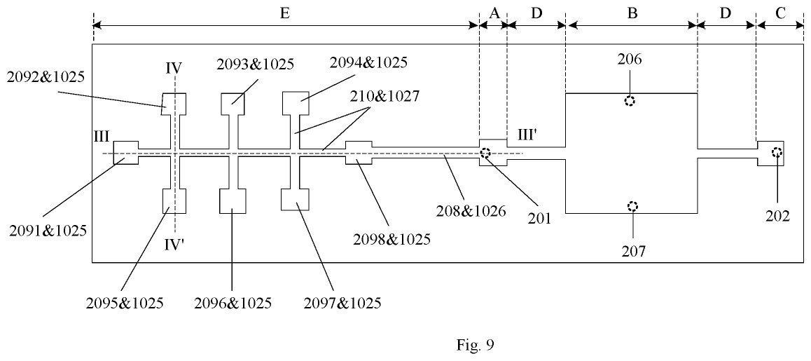

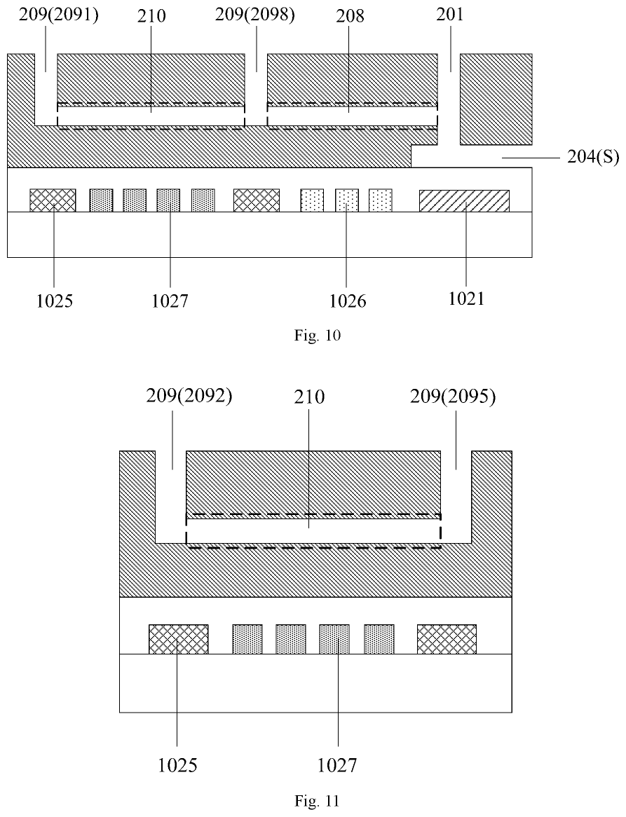

In some embodiments, in the microfluidic chip provided in the embodiments of the present disclosure, as shown in FIGS. 9 to 11, the cover plate layer 002 may further include a first connection channel 208 and at least one solution storage recess 209, an orthographic projection of the first connection channel 208 on the substrate 101 and orthographic projections of all solution storage recesses 209 on the substrate 101 may not overlap an orthographic projection of the solution accommodating space S on the substrate 101; and the solution storage recess 209 is concaved inwards from a surface of a side of the cover plate layer 002 facing away from the substrate layer 001 towards the cover plate layer 002, the first connection channel 208 is located inside the cover plate layer 002, and the solution storage recess 209 is in communication with the solution inlet hole 201 through the first connection channel 208. In some embodiments, a region where the first connection channel 208 and all the solution storage recesses 209 are located may be an extraction region E, such that a combination with an extraction chip may be achieved, and extraction and amplification operations may be performed on a single microfluidic chip.

In some embodiments, in the microfluidic chip provided in the embodiments of the present disclosure, as shown in FIGS. 9 to 11, the solution storage recesses 209 may include at least one of a sample storage recess 2091, a magnetic bead and lysis solution storage recess 2092, a washing solution storage recess 2093, an eluate storage recess 2094, a lysis waste solution storage recess 2095, a washing waste solution storage recess 2096, a magnetic bead waste solution storage recess 2097, and a product storage recess 2098. In some embodiments, in the case of a plurality of solution storage recesses 209, as shown in FIGS. 9 to 11, the cover plate layer 002 may further include a second connection channel 210 enabling communication between the solution storage recesses 209, the second connection channel 210 is located inside the cover plate layer 002, an orthographic projection of the second connection channel 210 on the substrate 101 does not overlap the orthographic projection of the solution accommodating channel S on the substrate 101. In some embodiments, the second connection channel 210 is also located in the extraction region E.

In some embodiments, in the microfluidic chip provided in the embodiments of the present disclosure, as shown in FIGS. 9 to 11, the drive electrode layer 102 further includes: fourth electrodes 1025 corresponding one-to-one to the solution storage recesses 209, a plurality of second connection electrodes 1026 corresponding to the first connection channel 208 and arranged in an array, and a plurality of third connection electrodes 1027 corresponding to the second connection channel 210 and arranged in an array. In some embodiments, both the second connection electrode 1026 and the third connection electrodes 1027 employ active driving. The fourth electrode 1025, the second connection electrode 1026, and the third connection electrodes 1027 may provide a driving force for flow of the solution in the extraction region E, to improve the flow patency of the solution in the extraction region E.

In some embodiments, in the microfluidic chip provided in the embodiments of the present disclosure, as shown in FIGS. 4, 5, 7, 10 and 11, the substrate layer 001 may further include a hydrophobic layer 103 arranged on an entire surface of a side of the drive electrode layer 102 facing away from the substrate 101. Since a reaction solution of the PCR amplification reaction is generally an aqueous solution, by providing a flat hydrophobic layer 103 on the side of the substrate layer 001 adjacent to the cover plate layer 002, it is possible to flexibly control contact angles of the droplets on the hydrophobic layer 103 by using the drive electrode layer 102 based on an electrowetting technique, so as to force the droplets to deform and displace.

Based on the same inventive concept, embodiments of the present disclosure provide a usage method for the microfluidic chip. A principle for solving a problem by the usage method is similar to that by the microfluidic chip, such that reference may be made to the implementation of the above microfluidic chip provided in the embodiments of the present disclosure for the implementation of the usage method provided in the embodiments of the present disclosure, which is not repeated herein.

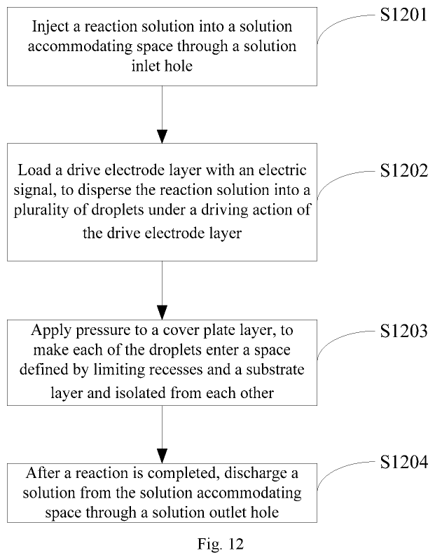

An embodiment of the present disclosure provides a usage method for the microfluidic chip, as shown in FIG. 12. The usage method includes:
S1201, inject a reaction solution into a solution accommodating space through a solution inlet hole;
S1202, load a drive electrode layer with an electric signal, to disperse the reaction solution into a plurality of droplets under a driving action of the drive electrode layer;
S1203, apply pressure to a cover plate layer, to make each of the droplets enter a space defined by limiting recesses and a substrate layer and isolated from each other; and
S1204, after a reaction is completed, discharge a solution from the solution accommodating space through a solution outlet hole.

In some embodiments, in the usage method provided in the embodiments of the present disclosure, the step of applying pressure to the cover plate layer, to make each of the droplets enter a space defined by the limiting recesses and the substrate layer and isolated from each other may be implemented specifically in two ways as follows.

One implementation way is as follows: inflate and pressurize the gas valve cavity, to make the gas valve cavity drive the plurality of limiting recesses to move towards the substrate layer until the opening surfaces of the limiting recesses make contact with the substrate layer, so as to make each of the droplets enter the space defined by the limiting recesses and the substrate layer and isolated from each other.

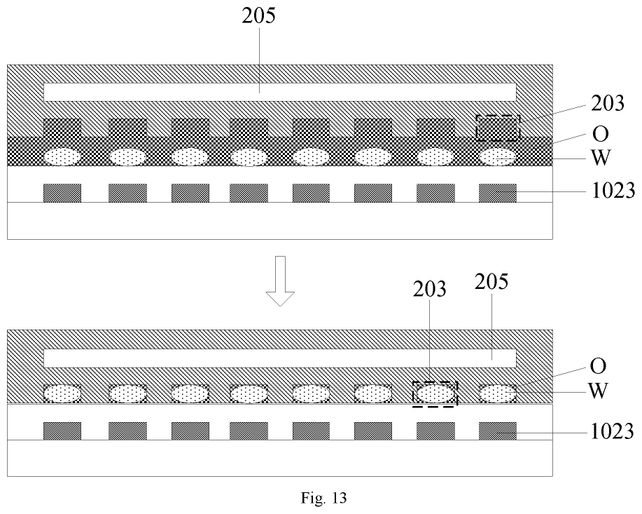

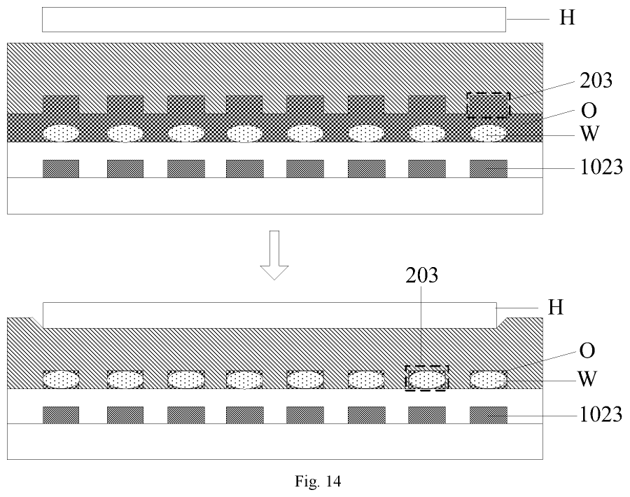

During specific implementation, with reference to FIGS. 4 and 13, a closed oil phase O such as a mineral oil or an electronic fluorinated solution may be added from the solution inlet hole 201 until the entire solution accommodating space S is filled. Then, an appropriate amount of aqueous phase PCR reaction solution is added again through the solution inlet hole 201 at the position of the first electrode 1021, and the excess oil phase O is discharged from the solution outlet hole 202. In this case, under a driving action of the first electrode 1021, the first connection electrode 1024 and the third electrodes 1023, the PCR reaction solution at the first electrode 1021 forms droplets W and is dispersed to each of the third electrodes 1023. After dispersion of the droplets W is completed and the droplets W are stably arranged at each of the third electrodes 1023, the solution inlet hole 201 is closed, and the gas valve cavity 205 at the reaction region B is inflated and pressurized, such that the opening surface of each limiting recess 203 in the solution accommodating space S moves down to make contact with the substrate layer 001, then the limiting recesses 203 are used for physically separating the arranged droplets W and the surrounding oil phase O, and the excess oil phase O flows out from the solution outlet hole 202. After the deformation of the cover plate layer 002 is stable, reaction unit distribution is completed by closing the solution inlet hole 201 and the solution outlet hole 202, so as to perform a subsequent temperature control cycle operation.

The other implementation way is as follows: apply pressure to the cover plate layer by using a weight on the side of the cover plate layer facing away from the substrate layer until the opening surfaces of the limiting recesses make contact with the substrate layer, so as to make each of the droplets enter the space defined by the limiting recesses and the substrate layer and isolated from each other. This implementation mode is similar to that described above, except that the cover plate layer 002 is pressed down by a weight H. Specifically, with reference to FIG. 14, a weight H having the same area as all the limiting recesses 1023 and the protrusions therebetween may be used for pressing down the cover plate layer 002, such that the opening surfaces of the plurality of limiting recesses 203 move downwards to make contact with the substrate layer 001, so as to store the droplets W into the spaces defined by the limiting recesses 203 and the substrate layer 001, thereby completing the physical separation process of each droplet W. Furthermore, the weight H may be integrated into a subsequent heating and temperature control device, for example, arranged on a cover plate of a heating instrument, such that covering the instrument is equivalent to applying the weight H, and a subsequent experimental procedure may be performed immediately.

Based on the same inventive concept, embodiments of the present disclosure provide the above microfluidic system. A principle for solving a problem by the microfluidic system is similar to that by the microfluidic chip, such that reference may be made to the implementation of the above microfluidic chip provided in the embodiments of the present disclosure for the implementation of the microfluidic system provided in the embodiments of the present disclosure, which is not repeated herein.

It will be apparent to those skilled in the art that various modifications and variations can be made to the embodiments of the present disclosure without departing from the spirit and scope of the embodiments of the present disclosure. Thus, if modifications and variations to the embodiments of the present disclosure fall within the scope of the appended claims of the present disclosure and their equivalents, it is intended that the present disclosure cover such modifications and variations as well.

1. A microfluidic chip, comprising:
a substrate layer, wherein the substrate layer comprises a substrate and a drive electrode layer disposed on the substrate; and
a cover plate layer, arranged opposite the substrate layer, wherein:
a space between the cover plate layer and the substrate layer form a solution accommodating space;
the cover plate layer comprises:
a solution inlet hole, penetrating a thickness direction of the cover plate layer;
a solution outlet hole, penetrating the thickness direction of the cover plate layer; and
a plurality of limiting recesses, arranged in an array on a side of the cover plate layer facing the substrate layer;
wherein the solution inlet hole, the solution outlet hole and the plurality of limiting recesses are in communication with the solution accommodating space; and
an end surface of the solution inlet hole adjacent to the substrate layer, an end surface of the solution outlet hole adjacent to the substrate layer, and opening surfaces of the plurality of limiting recesses are arranged substantially flush with one another.

2. The microfluidic chip according to claim 1, wherein the cover plate layer further comprises a reaction recess, the reaction recess arranged on the side of the cover plate layer facing the substrate layer, and the reaction recess and the substrate layer form the solution accommodating space; and
a bottom surface of the reaction recess is arranged substantially flush with the end surface of the solution inlet hole adjacent to the substrate layer, the end surface of the solution outlet hole adjacent to the substrate layer, and the opening surfaces of the plurality of limiting recesses.

3. The microfluidic chip according to claim 2, wherein the reaction recess and the plurality of limiting recesses are integrally injection-molded.

4. The microfluidic chip according to claim 1, wherein the cover plate layer further comprises a gas valve cavity independent from the plurality of limiting recesses, a gas inlet channel and a gas outlet channel, the gas inlet channel and the gas outlet channel are in communication with the gas valve cavity;
the gas valve cavity is arranged on a side of the plurality of limiting recesses facing away from the substrate layer; and
an orthographic projection of the gas valve cavity on the substrate covers orthographic projections of the plurality of limiting recesses on the substrate.

5. The microfluidic chip according to claim 4, wherein the gas valve cavity and the plurality of limiting recesses are integrally injection-molded; or
a portion where the gas valve cavity is located and a portion where the plurality of limiting recesses are located are fixedly connected with each other through glue.

6. The microfluidic chip according to claim 1, wherein a volume of each of the limiting recesses is substantially a same.

7. The microfluidic chip according to claim 1, wherein the drive electrode layer comprises:
a first electrode;
a second electrode; and
a plurality of third electrodes arranged in an array;
wherein an orthographic projection of the first electrode on the substrate covers an orthographic projection of the solution inlet hole on the substrate;
an orthographic projection of the second electrode on the substrate covers an orthographic projection of the solution outlet hole on the substrate; and
orthographic projections of the plurality of third electrodes on the substrate and the orthographic projections of the plurality of limiting recesses on the substrate overlap each other.

8. The microfluidic chip according to claim 7, wherein an orthographic projection of one of the plurality of limiting recesses on the substrate covers an orthographic projection of at least one of the third electrodes on the substrate.

9. The microfluidic chip according to claim 7, wherein the substrate layer further comprises: a plurality of transistors arranged between the substrate and the drive electrode layer, and the plurality of transistors are electrically connected with the third electrodes.

10. The microfluidic chip according to claim 7, wherein the drive electrode layer further comprises a plurality of first connection electrodes; and
the plurality of first connection electrodes are arranged between the first electrode and the plurality of third electrodes; and
the plurality of first connection electrodes are arranged between the second electrode and the plurality of third electrodes.

11. The microfluidic chip according to claim 10, wherein a main channel region, a connection channel region, and at least one branch channel region are provided between the first electrode and the plurality of third electrodes, and between the second electrode and the plurality of third electrodes separately; and
the at least one branch channel region is connected with the main channel region by means of the connection channel region;
the main channel region is arranged adjacent to the first electrode and the second electrode;
the branch channel region is arranged adjacent to the plurality of third electrodes; and
each of the main channel region, the connection channel region, and the branch channel regions is provided with a plurality of the first connection electrodes separately.

12. The microfluidic chip according to claim 1, wherein the cover plate layer further comprises a first connection channel and at least one solution storage recess;
an orthographic projection of the first connection channel on the substrate and an orthographic projection of the at least one solution storage recess on the substrate do not overlap an orthographic projection of the solution accommodating space on the substrate;
the solution storage recess is concaved inwards from a surface of a side of the cover plate layer facing away from the substrate layer towards the cover plate layer;
the first connection channel is arranged inside the cover plate layer; and
the solution storage recess is in communication with the solution inlet hole through the first connection channel.

13. The microfluidic chip according to claim 12, wherein the cover plate layer further comprises a plurality of solution storage recesses, and a second connection channel enabling communication between the solution storage recesses;
the second connection channel is arranged inside the cover plate layer; and
an orthographic projection of the second connection channel on the substrate does not overlap the orthographic projection of the solution accommodating space on the substrate.

14. The microfluidic chip according to claim 13, wherein the drive electrode layer further comprises: a plurality of fourth electrodes corresponding one-to-one to the solution storage recesses;
a plurality of second connection electrodes corresponding to the first connection channel and arranged in an array; and
a plurality of third connection electrodes corresponding to the second connection channel and arranged in an array.

15. The microfluidic chip according to claim 12, wherein the solution storage recesses comprise at least one of a sample storage recess, a magnetic bead and lysis solution storage recess, a washing solution storage recess, an eluate storage recess, a lysis waste solution storage recess, a washing waste solution storage recess, a magnetic bead waste solution storage recess, or a product storage recess.

16. The microfluidic chip according to claim 1, wherein the substrate layer further comprises a hydrophobic layer arranged on an entire surface of a side of the drive electrode layer away from the substrate.

17. A microfluidic system, comprising the microfluidic chip according to claim 1.

18. A usage method for the microfluidic chip according to claim 1, comprising:
injecting a reaction solution into the solution accommodating space through the solution inlet hole;
loading the drive electrode layer with an electric signal, to disperse the reaction solution into a plurality of droplets under a driving action of the drive electrode layer;
applying pressure to the cover plate layer, to make each of the droplets enter a space defined by the limiting recesses and the substrate layer and isolated from each other; and
after a reaction is completed, discharging a solution from the solution accommodating space through the solution outlet hole.

19. The usage method according to claim 18, wherein the cover plate layer further comprises a gas valve cavity independent from the plurality of limiting recesses, a gas inlet channel and a gas outlet channel, the gas inlet channel and the gas outlet channel are in communication with the gas valve cavity; the gas valve cavity is arranged on a side of the plurality of limiting recesses facing away from the substrate layer; and an orthographic projection of the gas valve cavity on the substrate covers orthographic projections of the plurality of limiting recesses on the substrate;
wherein the applying pressure to the cover plate layer, to make each of the droplets enter a space defined by the limiting recesses and the substrate layer and isolated from each other specifically comprises:
inflating and pressurizing the gas valve cavity, to make the gas valve cavity drive the plurality of limiting recesses to move towards the substrate layer until the opening surfaces of the limiting recesses make contact with the substrate layer, so as to make each of the droplets enter the space defined by the limiting recesses and the substrate layer and isolated from each other.

20. The usage method according to claim 18, wherein the applying pressure to the cover plate layer, to make each of the droplets enter a space defined by the limiting recesses and the substrate layer and isolated from each other specifically comprises:
applying pressure to the cover plate layer by using a weight on the side of the cover plate layer facing away from the substrate layer until the opening surfaces of the limiting recesses make contact with the substrate layer, so as to make each of the droplets enter the space defined by the limiting recesses and the substrate layer and isolated from each other.
